(19) United States
(12) Patent Application Publication
(10) Pub. No.: US 2012/0292720 A1
(43) Pub. Date: Nov. 22, 2012

(54) METAL GATE STRUCTURE AND MANUFACTURING METHOD THEREOF

(76) Inventors: Chih-Chung Chen, Tainan City (TW); Yu-Ren Wang, Tainan City (TW); Tsuo-Wen Lu, Kaohsiung City (TW); Wen-Yi Teng, Kaohsiung City (TW)

(21) Appl. No.: 13/109,999

(22) Filed: May 18, 2011

(51) Int. Cl. H01L 29/772; H01L 21/336

(52) U.S. Cl. 257/411; 438/287; 257/E29.242; 257/E21.409

(57) ABSTRACT

A metal gate structure includes a high dielectric constant (high-K) gate dielectric layer, a metal gate having at least a U-shaped work function metal layer positioned on the high-K gate dielectric layer, and a silicon carbonitride (SiCN) seal layer positioned on sidewalls of the high-K gate dielectric layer and of the metal gate.

### BACKGROUND OF THE INVENTION

1. Field of the Invention

The invention relates to a metal gate structure and a manufacturing method thereof, and more particularly, to a metal gate structure and a manufacturing method applied with the gate last process.

2. Description of the Prior Art

With a trend towards scaling down size of the semiconductor device, conventional methods, which are used to achieve optimization, such as reducing thickness of the gate dielectric layer, for example the thickness of silicon dioxide layer, have faced problems such as leakage current due to tunneling effect. In order to keep progression to next generation, high-K materials are used to replace the conventional silicon oxide to be the gate dielectric layer because it effectively decreases physical limit thickness, reduces leakage current, and obtains equivalent capacitor in an identical equivalent oxide thickness (EOT).

On the other hand, the conventional polysilicon gate also has faced problems such as inferior performance due to boron penetration and unavoidable depletion effect which increases equivalent thickness of the gate dielectric layer, reduces gate capacitance, and worsens a driving force of the devices. Thus work function metals are developed to replace the conventional polysilicon gate to be the control electrode that competent to the high-K gate dielectric layer.

However, the high-K material is susceptible to following processes. For example, the high-K gate dielectric layer may be exposed and thus is easily oxidized during the following processes. Consequently, the exposed and oxidized high-K gate dielectric suffers degrading or uncertainty to its dielectric constant and thus the reliability of the gate structure is adversely impacted. The exposed high-K gate dielectric layer may be damaged in the processes and thus the electrical performance of the semiconductor device is deteriorated. Therefore there is always a continuing need in the semiconductor processing art to develop the semiconductor device renders high-K gate dielectric layer and gate structure having superior reliability even though the conventional silicon dioxide or silicon oxynitride gate dielectric layer is replaced by the high-K gate dielectric layer and the conventional polysilicon gate is replaced by the metal gate.

### SUMMARY OF THE INVENTION

According to an aspect of the present invention, there is provided a metal gate structure. The metal gate structure includes a high-K gate dielectric layer, a metal gate having at least a U-shaped work function metal layer positioned on the high-K gate dielectric layer, and a silicon carbonitride (SiCN) seal layer positioned on sidewalls of the high-K gate dielectric layer and the metal gate.

According to another aspect of the present invention, there is provided a manufacturing method for a metal gate structure. The manufacturing method includes providing a substrate having a dummy gate formed thereon, the dummy gate comprising at least a sacrificial layer; performing an atomic layer deposition (ALD) method to form a SiCN seal layer on the substrate and the dummy gate, the ALD method comprising introducing a hydrocarbon (CₓH_{y}) gas; removing the sacrificial layer of the dummy gate to form a gate trench on the substrate; and forming a metal gate in the gate trench.

According to the metal gate structure and the manufacturing method thereof provided by the present invention, the ALD method is provided to form the SiCN seal layer having low wet etching rate on the sidewalls of the metal gate and the high-K gate dielectric layer. Since the SiCN seal layer has the low wet etching rate, it renders superior protection to the high-K gate dielectric layer in the following etching or cleaning processes. And thus oxidation of the high-K gate dielectric layer is avoided. Accordingly, the manufacturing method for a metal gate structure provided by the present invention provides a metal gate structure having superior reliability.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic drawings illustrating a manufacturing method for a metal gate structure provided by a first preferred embodiment of the present invention.

FIGS. 7-10 are schematic drawings illustrating a manufacturing method for a metal gate structure provided by a second preferred embodiment of the present invention.

### DETAILED DESCRIPTION

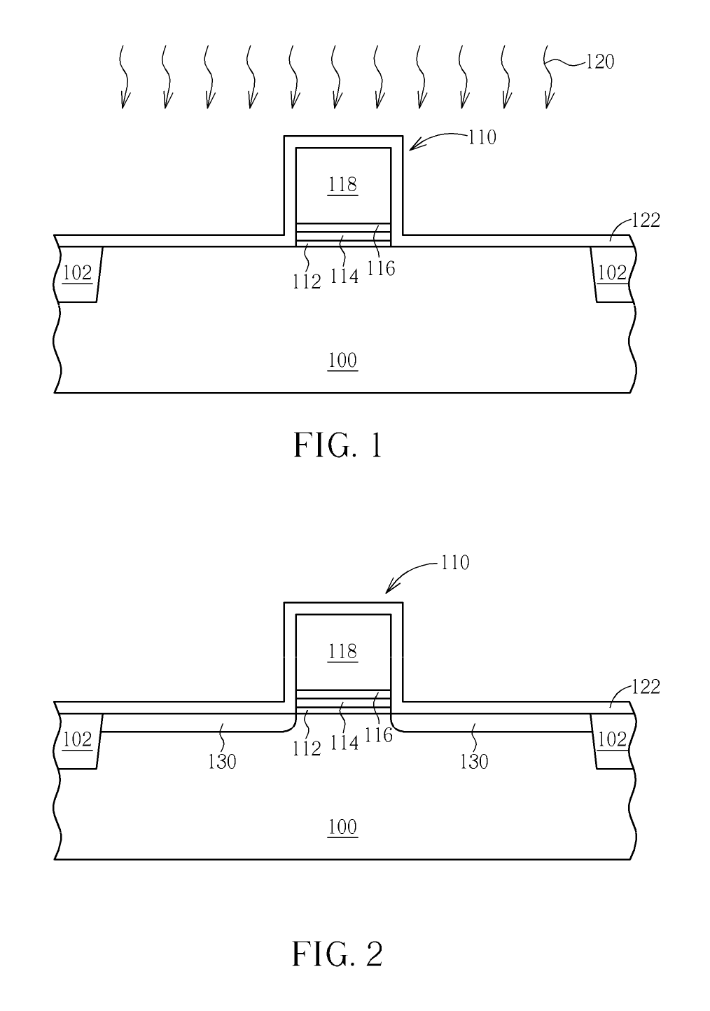

Please refer to FIGS. 1-6, which are schematic drawings illustrating a manufacturing method for a metal gate structure provided by a first preferred embodiment of the present invention. It is noteworthy that the first preferred embodiment is integrated with a gate last process. As shown in FIG. 1, a substrate 100 such as a silicon substrate, a silicon-containing substrate, or a silicon-on-insulator (SOI) substrate is provided. The substrate 100 includes a plurality of shallow trench isolations (STIs) 102 for providing electrical isolation formed therein. Next, a dummy gate 110 is formed on the substrate 100. The dummy gate 110 includes an interfacial layer 112, a gate dielectric layer 114, a bottom barrier layer 116, an sacrificial layer 118 and a patterned hard mask (not shown) sequentially and upwardly stacked on the substrate 100. The bottom barrier layer 116 can include titanium nitride (TiN), but not limited to this. The sacrificial layer 118 can include polysilicon. It is noteworthy that the preferred embodiment is integrated with the high-K first process, therefore the gate dielectric layer 114 includes high-K material such as rare earth metal oxide. For example, the high-K gate dielectric layer 114 can include materials selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT) and barium strontium titanate (BaₓSr₁₋ₓTiO₃, BST).

Please still refer to FIG. 1. Next, an ALD method 120 is performed to form a SiCN seal layer 122 on the substrate 100 and the dummy gate 110. The SiCN seal layer 122 includes a thickness, and the thickness is smaller than 40 angstroms (Å). Those skilled in the art would easily realize that the ALD method 120 is to form a desired layer by absorption reactions between the process gas and the surface on which the layer is formed. In the preferred embodiment, the ALD method 120 includes a step of introducing a precursor, and the precursor includes disilane (DIS), dichlorosilane (DCS), hexa-chloride-disilane (HCD) or silane, but not limited to this. More important, the ALD method 120 provided by the preferred embodiment includes introducing hydrocarbon (CₓH_{y}) gas, and the hydrocarbon gas includes ethylene (C₂H₄), but not limited to this. In addition, the ALD method 120 provided by the preferred embodiment is preferably performed without using plasma.

According to the preferred embodiment, hydrocarbon such as ethylene serves as the source of carbon. Therefore the seal layer 122 comprising SiCN is formed on the substrate 100 and the dummy gate 110. More important, the SiCN seal layer 122 formed by the ALD method 120 provided by the preferred embodiment is a dense layer with low wet etching rate. The wet etching rate of the SiCN seal layer 122 is lower than 5. Please refer to Table 1, which presents the wet etching rate of the SiCN seal layer 122 formed by the ALD layer 120 provided by the preferred embodiment and wet etching rates of SiCN or SiN layers formed by other methods:

TABLE 1

| | Layer | | | | | | | |
|---|---|---|---|---|---|---|---|---|
| | SiCN | | | SiN | | | | |
| | Method | | | | | | | |
| | ALD | CVD | | | | PEALD | | |
| Precursor | DCS | BTBAS | CHCD | DIS | HCD | DCS | | |
| Process temperature | 630° C. | 550° C. | 580° C. | 700° C. | 580° C. | 450° C. | 500° C. | 550° C. |
| Wet etching | 0.91 | 6.31 | 6.06 | 9.74 | 28.69 | 33.54 | 15.60 | 7.94 |
| rate to DHF | | | | | | | | |
| Wet etching rate | 4.72 | 27.81 | 45.00 | 94.57 | 249.00 | 170.99 | 112.90 | 73.88 |
| to phosphoric acid | | | | | | | | |
| Refraction index | 2.01 | 1.9 | 2.05 | 1.96 | 2.01 | 1.89 | 1.92 | 1.95 |
| (RI) | | | | | | | | |

Unit: Ang/min.

Table 1 presents the wet etching rate of the SiCN seal layer 122 formed by the ALD layer 120 provided by the preferred embodiment, the wet etching rates of SiCN or SiN layers formed by the chemical vapor deposition (CVD) and the wet etching rates of SiN layers formed by the plasma enhanced ALD (PEALD). Furthermore, Table 1 further presents the wet etching rates of layers formed by CVD method with different precursor such as bis(tertiary-butylamino)silane (BTBAS), carbon-sourced hexachloride disilane (CHCD), disilane (DIS), and hexachloride disilane (HCD) introduced. Table 1 also presents the wet etching rates of the layers formed by PEALD with introducing DCS and different process temperature. According to Table 1, the wet etching rates of the SiCN seal layer 122 to DHF and phosphoric acrid are all lower than 5 that is much lower than the etching rates of the SiCN or SiN layer formed by other methods.

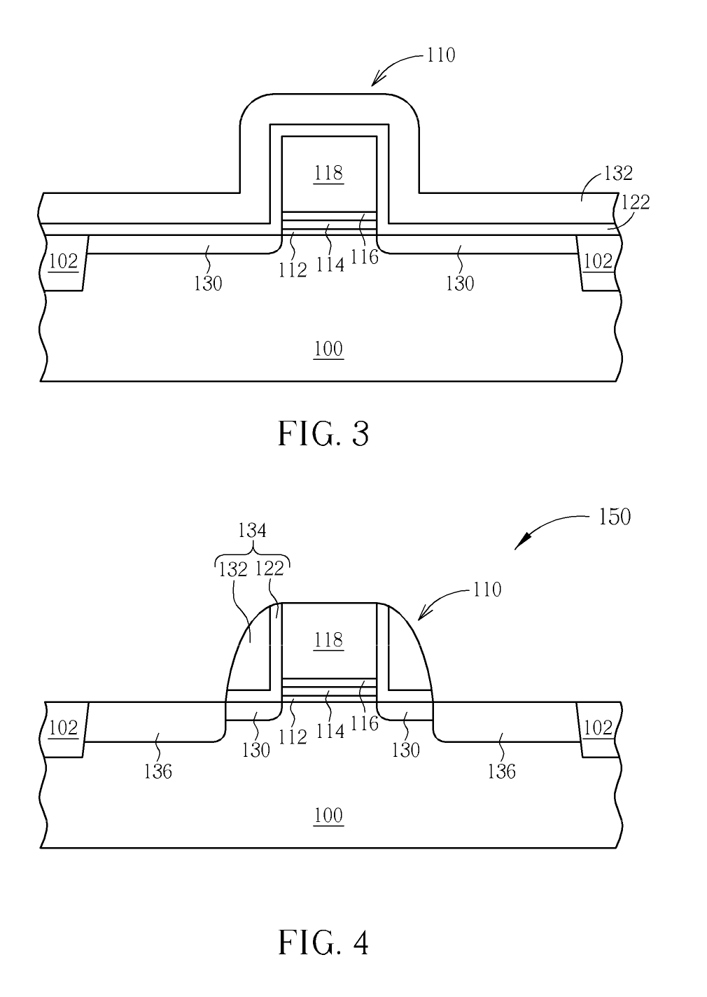

Please refer to FIG. 2 and FIG. 3. After forming the SiCN seal layer 122, lightly-doped drains (LDDs) 130 are formed in the substrate 100 respectively at two sides of the dummy gate 110 as shown in FIG. 2. Then, as shown in FIG. 3, an insulating layer 132 is formed on the substrate 100 and the dummy gate 110. The insulating layer 132 is preferably a silicon oxide layer, but not limited to this.

Please refer to FIG. 4. Next, the insulating layer 132 and the SiCN seal layer 122 are etched back to form a spacer 134 on sidewalls of the dummy gate 110. As shown in FIG. 4, the spacer 134 includes the insulating layer 132 and the L-shaped SiCN seal layer 122. After forming the spacer 134, a source/drain 136 is formed in the substrate 100 respectively at two sides of the spacer 134. Consequently, a semiconductor 150 is formed. It is noteworthy that during etching back the insulating layer 132 and the SiCN seal layer 122, the SiCN seal layer 122 renders superior protection to the high-K gate dielectric layer 114 due to its low wet etching rate. Consequently, the high-K gate dielectric layer 114 protected by the SiCN seal layer 122 is impervious to the etching back process.

More important, it is well-known that selective strain scheme (SSS) such as a selective epitaxial growth (SEG) method is usually used to form the source/drain 136. In detail, the SSS is to form a recess (not shown) in the substrate 100 at two sides of the spacer 134. Subsequently, proper cleaning step is performed to clean the recesses and followed by performing the SEG method to form an epitaxial layer having SiGe for p-type semiconductor device or an epitaxial layer having SiC for n-type semiconductor device respectively in each recess. The formed epitaxial layers serves as the source/drain 136. Since the SiCN seal layer 122 provided by the preferred embodiment have the advantage of low wet etching rate, it renders superior protection to the high-K gate dielectric layer 114 in the etching process used to form the recesses and in the cleaning process used to clean the recesses.

Additionally, it is well-known to those skilled in the art that a silicide (not shown) is usually formed on the surface of source/drain 136 for reducing resistance. The silicide is formed by firstly forming a metal layer on the substrate and subsequently performing a thermal process. Thus the metal layer is reacted with the silicon in the source/drain 136 and transitional silicides are formed. Then, a wet etching process is performed to remove the un-reacted metal and followed by performing another thermal process to transfer the transitional silicides into silicides. Since the SiCN seal layer 122 provided by the preferred embodiment has the advantage of low wet etching rate, it renders superior protection to the high-K gate dielectric layer 114 during the wet etching process used to remove the un-reacted metal layer.

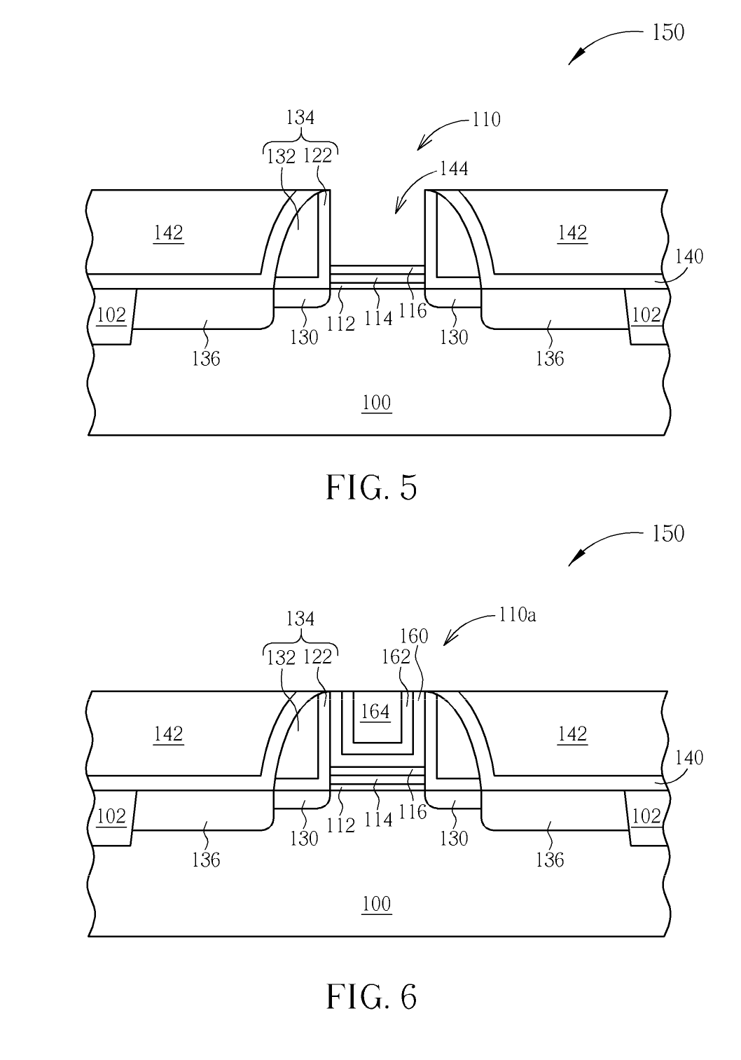

Please refer to FIG. 5. Next, a contact etch stop layer (CESL) 140 and an inter-layer dielectric (ILD) layer 142 are sequentially formed on the substrate 100 and the dummy gate 110. Then, a planarization process is performed to remove a portion of the ILD layer 142, a portion of the CESL 140 and the patterned hard mask. Consequently, the sacrificial layer 118 of the dummy gate 110 is exposed. Subsequently, the sacrificial layer 118 is removed to form a gate trench 144 by performing an etching process. In the etching process, the bottom barrier layer 116 serves as an etching stop layer for protecting the high-K gate dielectric layer 114. As mentioned above, since the preferred embodiment is integrated with the high-K first process, the high-K gate dielectric layer 114 is remained in the gate trench 144.

Please refer to FIG. 6. Next, a work function metal layer 160, a top barrier layer 162, and a filling metal layer 164 are sequentially formed on the high-K gate dielectric layer 114 in the gate trench 144. Furthermore, an etching stop layer is selectively formed between the bottom barrier layer 116 and the work function metal layer 160 if required. The work function metal layer 160 includes proper material for different conductivity types of the semiconductor device 150. For example, when the semiconductor device 150 is an n-type semiconductor device, the work function metal layer 160 includes metal materials having work function between 3.9 eV and 4.3 eV. In another exemplar, when the semiconductor device 150 is a p-type semiconductor device, the work function metal layer 160 includes metal materials having work function between 4.8 eV and 5.2 eV. Since the material choice for the work function metal layer 160 is well-known to those skilled in the art, the details are omitted herein in the interest of brevity. The top barrier layer 162 includes TiN, but not limited to this. The filling metal layer 164 includes metals or metal oxides having superior gap-filling characteristic and low resistance such as aluminum (Al), titanium aluminide (TiAl), or titanium aluminum oxide (TiAlO), but not limited to this.

Please still refer to FIG. 6. Then, a planarization process such as a CMP process is performed to remove unnecessary filling metal layer 164, top barrier layer 162, and work function metal layer 160. Consequently, a metal gate 110a is formed. As shown in FIG. 6, a cross-sectional view of the high-K gate dielectric layer 114 includes a flat shape, and cross-sectional views of the work function metal layer 160 and the top barrier layer 162 formed on the high-K gate dielectric layer 114 respectively include a U shape. And the SiCN seal layer 122 is formed on the sidewalls of the high-K gate dielectric layer 114 and the metal gate 110a. Furthermore, the ILD layer 142 and the CESL 140 can be selectively removed and sequentially reformed for improving performance of the semiconductor device in the preferred embodiment.

According to the metal gate structure and the manufacturing method thereof provided by the present invention, the ALD method 120 is performed to form the SiCN seal layer 122 having low wet etching rate on the sidewalls of the metal gate 110a and the high-K gate dielectric layer 112. Since the SiCN seal layer 122 has the low wet etching rate, it renders superior protection to the high-K gate dielectric layer 114 in the following processes such as the etching process used to form the recesses for the SEG method, the cleaning process for cleaning the recesses, the etching process used to remove the un-reacted metal layer in the silicide process, and any necessary wet cleaning process required by semiconductor fabricating processes. Accordingly, the high-K gate dielectric layer 114 is protected from oxidation and thus reliability is improved.

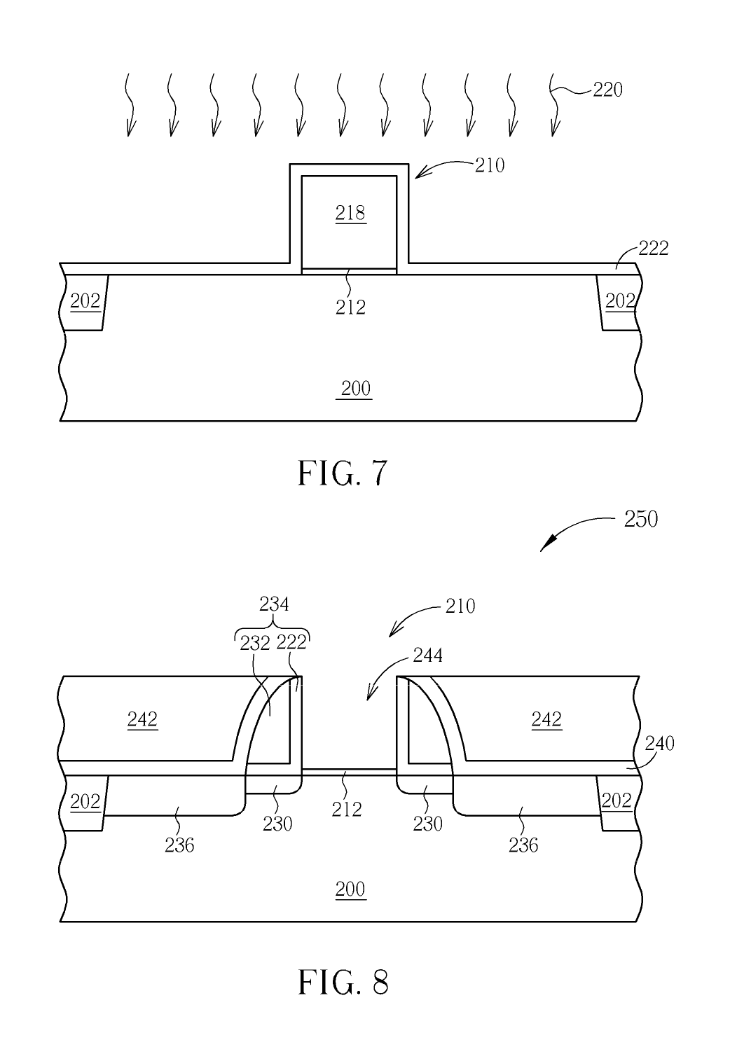

Please refer to FIGS. 7-10, which are schematic drawings illustrating a manufacturing method for a metal gate structure provided by a second preferred embodiment of the present invention. The second preferred embodiment is also integrated with the gate last process. As shown in FIG. 7, a substrate 200 such as a silicon substrate, a silicon-containing substrate, or a SOI substrate is provided. The substrate 200 includes a plurality of STIs 202 for providing electrical isolation formed therein. Next, a dummy gate 210 is formed on the substrate 200. The dummy gate 210 includes a gate dielectric layer 212, a sacrificial layer 218, and a patterned hard mask (not shown) sequentially and upwardly stacked on the substrate 200. The gate dielectric layer 212 is formed between the sacrificial layer 218 and the substrate 200. As mentioned above, the sacrificial layer 218 can include polysilicon. It is noteworthy that the preferred embodiment is integrated with the high-K last process, therefore the gate dielectric layer 212 is preferably a conventional silicon oxide layer.

Please still refer to FIG. 7. Next, an ALD method 220 is performed to form a SiCN seal layer 222 on the substrate 200 and the dummy gate 210. The SiCN seal layer 222 includes a thickness, and the thickness is smaller than 40 Å. In the preferred embodiment, the ALD method 220 includes a step of introducing a precursor, and the precursor includes DIS, DCS, HCD, or silane, but not limited to this. More important, the ALD method 220 provided by the preferred embodiment includes introducing hydrocarbon (CₓH_{y}) gas, and the hydrocarbon gas includes C₂H₄, but not limited to this. In addition, the ALD method 220 provided by the preferred embodiment is preferably performed without using plasma.

According to the preferred embodiment, hydrocarbon such as ethylene serves as the source of carbon. Therefore the seal layer 222 comprising SiCN is formed on the substrate 200 and the dummy gate 210. More important, the SiCN seal layer 222 formed by the ALD method 220 provided by the preferred embodiment is a dense layer with low wet etching rate. The wet etching rate of the SiCN seal layer 122 is lower than 5. It is noticeable that the wet etching rate of the SiCN seal layer 222 formed by the ALD layer 220 provided by the preferred embodiment and wet etching rates of SiCN or SiN layers formed by other methods, such as CVD or PEALD, also presented in Table 1, therefore those details are omitted herein in the interest of brevity. According to Table 1, it is found that the wet etching rates of the SiCN seal layer 222 to DHF and phosphoric acrid are all lower than 5 that is much lower than the etching rates of the SiCN or SiN layer formed by other methods.

Please refer to FIG. 8. After forming the SiCN seal layer 222, LDDs 230 are formed in the substrate 200 respectively at two sides of the dummy gate 210. Then, an insulating layer 232 is formed on the substrate 200 and the dummy gate 210. The insulating layer 232 is preferably a silicon oxide layer, but not limited to this. Next, the insulating layer 232 and the SiCN seal layer 222 are etched back to form a spacer 234 on sidewalls of the dummy gate 210. As shown in FIG. 8, the spacer 234 includes the insulating layer 232 and the L-shaped SiCN seal layer 222. After forming the spacer 234, a source/drain 236 is formed in the substrate 200 respectively at two sides of the spacer 234. Consequently, a semiconductor 250 is formed. Since the above mentioned steps in the second preferred embodiment are substantially the same the those in the first preferred embodiment, those details are omitted for simplicity.

Please still refer to FIG. 8. Next, a CESL 240 and an ILD layer 242 are sequentially formed on the substrate 200 and the dummy gate 210. Then, a planarization process is performed to remove a portion of the ILD layer 242, a portion of the CESL 240, and the patterned hard mask. Accordingly, the sacrificial layer 218 of the dummy gate 210 is exposed. Subsequently, the sacrificial layer 218 is removed to form a gate trench 244 by performing an etching process. In the etching process, the gate dielectric layer 212 serves as an etching stop layer for protecting the substrate 200. As mentioned above, since the preferred embodiment is integrated with the high-K last process, the gate dielectric layer 212 is consumed and at least a portion of the gate dielectric layer 212 is removed during removing the sacrificial layer 218. Consequently, the gate dielectric layer 212 is exposed in the bottom of the gate trench 244. More important, the remained gate dielectric layer serves as an interfacial layer 212 in the following processes. In a modification to the present preferred embodiment, the gate dielectric layer can be entirely removed and followed by reforming an interfacial layer 212.

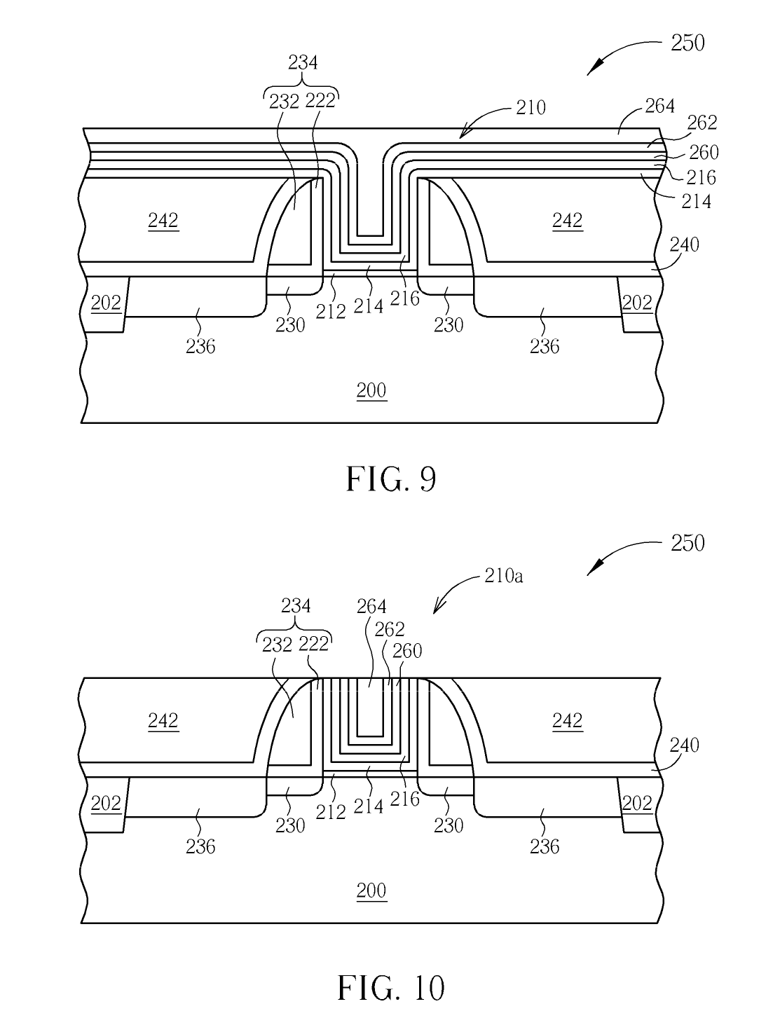

Please refer to FIG. 9. Then, a high-K gate dielectric layer 214, a bottom barrier layer 216, a work function metal layer 260, a top barrier layer 262, and a filling metal layer 264 are sequentially formed on the interfacial layer 212 in the gate trench 244. Furthermore, an etching stop layer is selectively formed between the bottom barrier layer 262 and the work function metal layer 260 if required. As mentioned above, the high-K gate dielectric layer 214 can include rare earth metal oxide. For example, the high-K dielectric layer 214 includes materials selected from the group consisting of HfO₂, HfSiO₄, HfSiON, Al₂O₃, La₂O₃, Ta₂O₅, Y₂O₃, ZrO₂, SrTiO₃, ZrSiO₄, HfZrO₄, SrBi₂Ta₂O₉, SBT, PZT and BST. The work function metal layer 260 includes proper material for different conductivity types of the semiconductor device 250. For example, when the semiconductor device 250 is an n-type semiconductor device, the work function metal layer 260 includes metal materials having work function between 3.9 eV and 4.3 eV. In another exemplar, when the semiconductor device 250 is a p-type semiconductor device, the work function metal layer 260 includes metal materials having work function between 4.8 eV and 5.2 eV. Since the material choice for the work function metal layer 260 is well-known to those skilled in the art, the details are omitted herein in the interest of brevity. The bottom barrier layer 216 and the top barrier layer 262 can include TiN, but not limited to this. The filling metal layer 264 includes metals or metal oxides having superior gap-filling characteristic and low resistance such as Al, TiAl, or TiAlO, but not limited to this.

Please refer to FIG. 10. Then, a planarization process such as a CMP process is performed to remove unnecessary filling metal layer 264, top barrier layer 262, work function metal layer 260, bottom barrier layer 216, and high-K gate dielectric layer 214. Consequently, a metal gate 210a is formed. As shown in FIG. 10, cross-sectional views of the high-K gate dielectric layer 214, the bottom barrier layer 216, the work function metal layer 260 and the top barrier layer 262 respectively include a U shape. And the high-K gate dielectric layer 214 is formed between the SiCN seal layer 222 and the metal gate 210a, that is between the SiCN seal layer 222 and the bottom barrier layer 216. Furthermore, the ILD layer 242 and the CESL 240 can be selectively removed and sequentially reformed for improving performance of the semiconductor device in the preferred embodiment. As mentioned above, since the SiCN seal layer 222 has low wet etching rate, the high-K gate dielectric layer 214 is protected from the adverse impact during removing the CESL 240 and the ILD layer 242 by the SiCN seal layer 222.

According to the metal gate structure and the manufacturing method thereof provided by the present invention, the ALD method 220 is performed to form the SiCN seal layer 122 having low wet etching rate formed on the sidewalls of the high-K gate dielectric layer 212 and the metal gate 210a. Since the SiCN seal layer 222 has the low wet etching rate, it renders superior protection to the high-K gate dielectric layer 214 in the following processes such as etching process used to form the recesses for SEG method, the cleaning process used to clean the recesses, the etching process used to remove the CESL 240 and the ILD layer 242, and any necessary wet cleaning process required by semiconductor fabricating processes. Accordingly, the high-K gate dielectric layer 212 is protected from oxidation and thus reliability is improved.

As mentioned above, according to the metal gate structure and the manufacturing method thereof provided by the present invention, the ALD method is provided to form the SiCN seal layer having low wet etching rate on the sidewalls of the metal gate and the high-K gate dielectric layer. Since the SiCN seal layer has the low wet etching rate, it renders superior protection to the high-K gate dielectric layer during the following etching or cleaning processes. And thus oxidation of the high-K gate dielectric layer is avoided. Accordingly, the manufacturing method for a metal gate structure provided by the present invention provides a metal gate structure having superior reliability.

Those skilled in the art will readily observe that numerous modifications and alterations of the device and method may be made while retaining the teachings of the invention.

What is claimed is:

1. A metal gate structure comprising:
a high dielectric constant (high-K) gate dielectric layer;
a metal gate having at least a U-shaped work function metal layer positioned on the high-K gate dielectric layer; and
a silicon carbonitride (SiCN) seal layer positioned on sidewalls of the high-K gate dielectric layer and the metal gate.

2. The metal gate structure according to claim 1, wherein the high-K gate dielectric layer comprises materials selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT) and barium strontium titanate (BaₓSr₁₋ₓTiO₃, BST).

3. The metal gate structure according to claim 1, further comprising an interfacial layer, and the high-K gate dielectric layer is positioned on the interfacial layer.

4. The metal gate structure according to claim 1, wherein a cross-sectional view of the high-K gate dielectric layer comprises a flat shape.

5. The metal gate structure according to claim 1, wherein a cross-sectional view of the high-K gate dielectric layer comprises a U shape.

6. The metal gate structure according to claim 5, wherein the high-K gate dielectric layer is positioned between the SiCN seal layer and the metal gate.

7. The metal gate structure according to claim 1, wherein the metal gate further comprises a filling metal layer stacked on the work function metal layer.

8. The metal gate structure according to claim 7, further comprising a bottom barrier layer positioned between the work function metal layer and the high-K gate dielectric layer, and a top barrier layer positioned between the work function metal layer and the filling metal layer.

9. The metal gate structure according to claim 1, wherein SiCN seal layer comprises an L shape.

10. The metal gate structure according to claim 1, wherein the SiCN seal layer comprises a thickness, and the thickness is smaller than 40 angstroms.

11. The metal gate structure according to claim 1, wherein a wet etching rate of the SiCN seal layer is smaller than 5.

12. A manufacturing method for a metal gate structure comprising:
providing a substrate having a dummy gate formed thereon, the dummy gate comprising at least a sacrificial layer;
performing an atomic layer deposition (ALD) method to form a SiCN seal layer on the substrate and the dummy gate, the ALD method
comprising introducing a hydrocarbon (CₓH_{y}) gas;
removing the sacrificial layer of the dummy gate to form a gate trench on the substrate; and
forming a metal gate in the gate trench.

13. The manufacturing method for a metal gate structure according to claim 12, wherein the hydrocarbon gas comprises ethylene (C₂H₄).

14. The manufacturing method for a metal gate structure according to claim 12, wherein the ALD method further comprises a step of introducing a precursor.

15. The manufacturing method for a metal gate structure according to claim 14, wherein the precursor comprises disilane (DIS), dichlorosilane (DCS), hexa-chloride-disilane (HCD) or silane.

16. The manufacturing method for a metal gate structure according to claim 12, further comprising:
forming lightly-doped drains (LDDs) in the substrate at two sides of the dummy gate;
forming an insulating layer on the substrate;
performing an etching back process to etch back the insulating layer and the SiCN seal layer to form a spacer on sidewalls of the dummy gate; and
forming a source/drain in the substrate at two sides of the spacer.

17. The manufacturing method for a metal gate structure according to claim 12, wherein the dummy gate further comprises an interfacial layer and a high-K gate dielectric layer, and the high-K gate dielectric layer is formed between the sacrificial layer and the interfacial layer.

18. The manufacturing method for a metal gate structure according to claim 17, wherein the high-K gate dielectric layer comprises a flat shape.

19. The manufacturing method for a metal gate structure according to claim 12, wherein the dummy gate further comprises a dielectric layer formed between the sacrificial layer and the substrate.

20. The manufacturing method for a metal gate structure according to claim 19, further comprising:
removing the sacrificial layer and a portion of the dielectric layer to form a gate trench on the substrate;
forming a U-shaped high-K gate dielectric layer in the gate trench; and
forming the metal gate in the gate trench.
